(19) United States
(12) Patent Application Publication
(10) Pub. No.: US 2010/0151389 A1
(43) Pub. Date: Jun. 17, 2010

(54) Alkaline developable photosensitive materials

(75) Inventors: Chun Geun Park, Seoul (KR); Moo Young Lee, Seongnam-si (KR); Seok Han, Seoul (KR); Seung Keun Kim, Seoul (KR); In Kyung Sung, Cheongju-si (KR); Hag Ju Lee, Cheonan-si (KR)

Correspondence Address: Edwin Oh;Rohm and Haas Electronic Materials LLC, 455 Forest Street, Marlborough, MA, 01752, US

(73) Assignee: Rohm and Haas Electronic Materials Korea Ltd., Chonan (KR)

(21) Appl. No.: 12/586,463

(22) Filed: Sep. 22, 2009

(30) Foreign Application Priority Data
Sep. 22, 2008 (KR) 10-2008-0092556

(51) Int. Cl. G03F 7/004

(52) U.S. Cl. 430/286.1

(57) ABSTRACT

Disclosed is a photosensitive resin composition suitable for forming barrier ribs for LCD pixels during a process for fabricating an LCD using an ink jet printing step. Also disclosed is a method of forming barrier ribs for LCD pixels using such photosensitive resin composition.

This application claims priority under 35 U.S.C. §119 the benefit of Korean Patent Application No. 10-2008-0092556, filed Sep. 22, 2008.

The present invention relates to a process for fabricating an LCD comprising an ink jet printing step. Particularly, the present invention relates to a photosensitive resin composition suitable for forming barrier ribs for defining LCD pixels during the fabrication of an LCD using an ink jet printing step.

More particularly, the present invention provides a super-hydrophobic photosensitive resin composition, which is used to produce super-hydrophobic barrier ribs for LCD pixels, and realizes sufficient adhesion and high diffusibility of inks when an ink jet printing step is performed by using RGB (red, green and blue) inks (i.e., when the RGB inks are sprayed or dropped into developed cells by way of ink jet printing) after the formation of the barrier ribs for LCD pixels. In addition, the barrier ribs (i.e. pattern for forming the pixels) formed from the composition ensure such an extreme degree of hydrophobicity that the inks maintain their droplets in a cell without overflowing toward another cell in spite of an excessive dropping amount.

In a process for fabricating a liquid crystal display (LCD), an ink jet printing step has been recently spotlighted as an advanced technological step that enables thinning of an LCD device and improves the productivity thereof, because the ink jet printing step allows skipping of two photolithographic steps and steps of patterning each color photoresist (PR) for RGB, thereby simplifying the overall process.

However, to carry out the ink jet printing step successfully, RGB inks should have sufficient adhesion and high wetting ability when they are sprayed or dropped into the developed cells (pixels). Additionally, the barrier ribs (i.e., pattern for forming the pixels) have to ensure such an extreme degree of hydrophobicity that the inks maintain their droplets in a cell without overflowing toward another cell in spite of an excessive dropping amount.

In a current method for satisfying both characteristics, it is known that a patterning step is carried out first by using a general passivation material for organic insulator, followed by post-treatment steps such as ashing and plasma treatment.

However, such post-treatment steps cause problems in that cost of equipment investment increases markedly and the productivity decreases significantly. Moreover, it has been recently found that such post-treatment steps are not practically applicable, since they may cause a non-uniform plasma concentration as LCD panels become larger.

The present invention has been made in an effort to solve the above-described problems associated with the prior art.

It is an object of the present invention to provide a transparent negative photosensitive super-hydrophobic material for ink jet printing, which has super-hydrophobicity, is sufficiently dissolved in a developing agent before and after exposure, and can realize a micropattern with a size up to 15 μm, preferably up to 10 μm. As used herein, the term “super-hydrophobicity” refers to a composition characterized by a contact angle value of >90° to distilled water and a contact angle value of >35° to ethyl CELLOSOLVE solvent.

The inventors of the present invention have conducted many studies to provide the above-described super-hydrophobic material for forming barrier ribs for pixels of an LCD, and have developed a transparent material for barrier ribs that has not only super-hydrophobicity but also sufficient post-exposure solubility, thereby forming a micropattern with a size up to 10 μm.

The above and other features of the present invention will now be described in detail with reference to certain example embodiments thereof illustrated in the accompanying drawings which are given hereinbelow by way of illustration only, and thus are not limitative of the present invention.

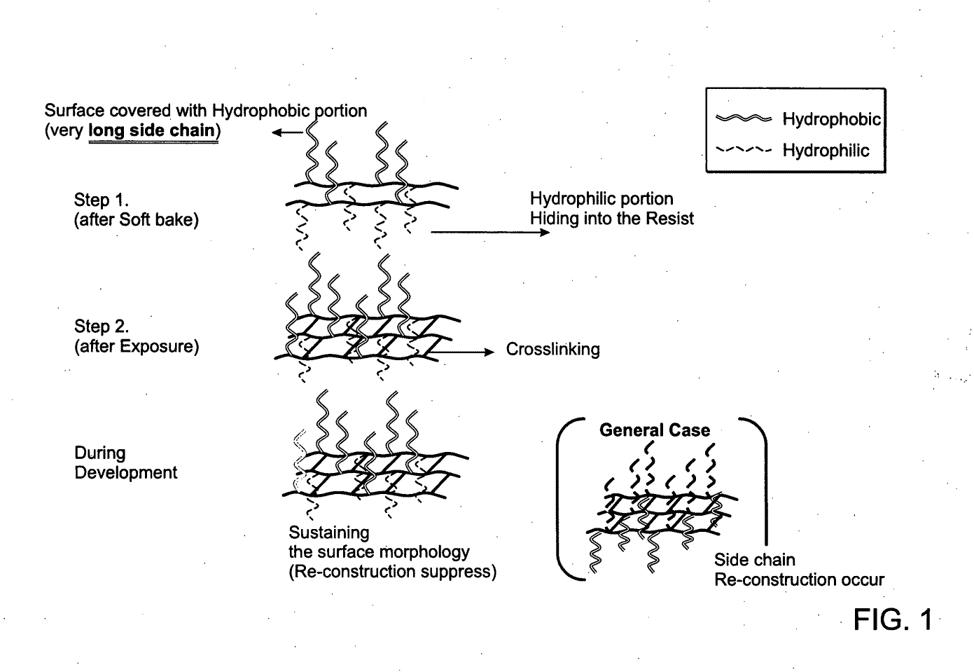

FIG. 1 is a schematic view illustrating the polymer chain reconstruction and photocuring steps.

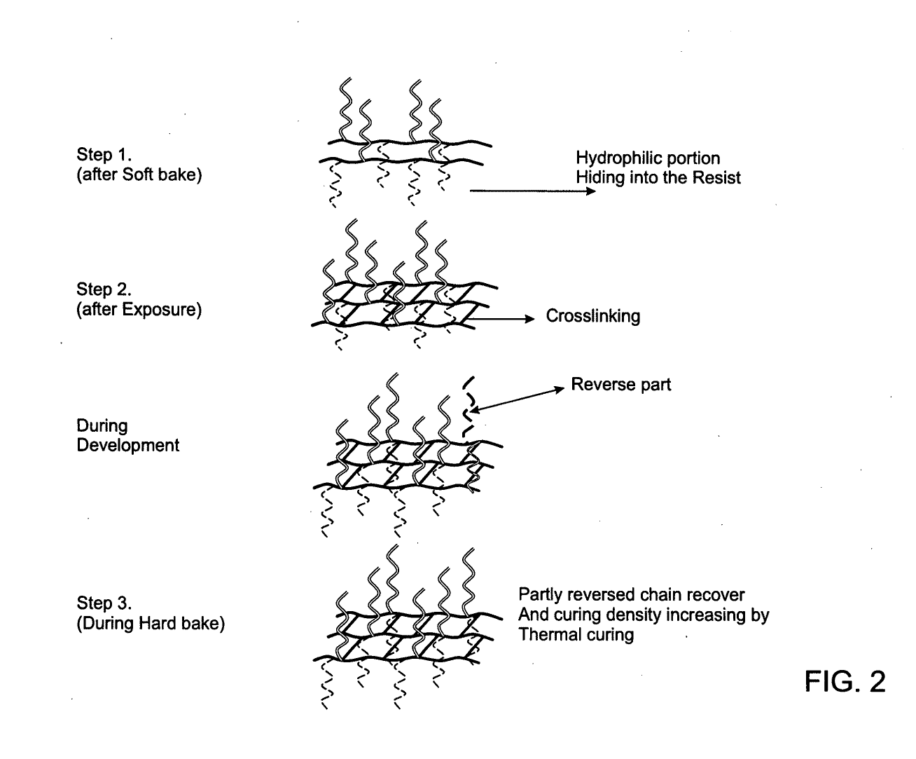

FIG. 2 is a schematic view illustrating the photocuring and thermal curing steps in the presence of thermally curable functional groups.

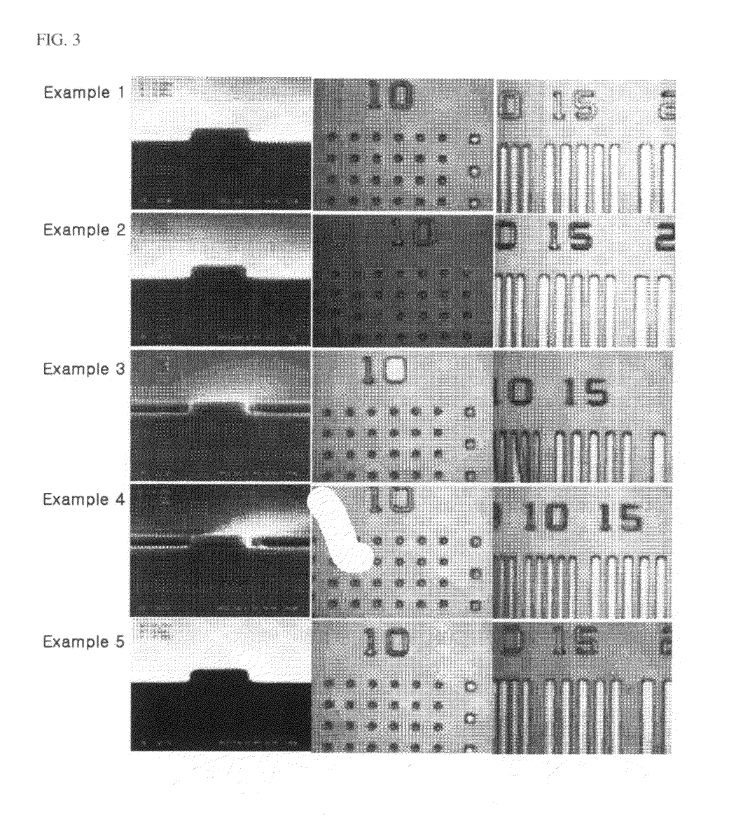

FIG. 3 is a photographic view of the barrier ribs produced according to Examples 1-5 taken by SEM (scanning electron microscopy) after the exposure, development and hard baking.

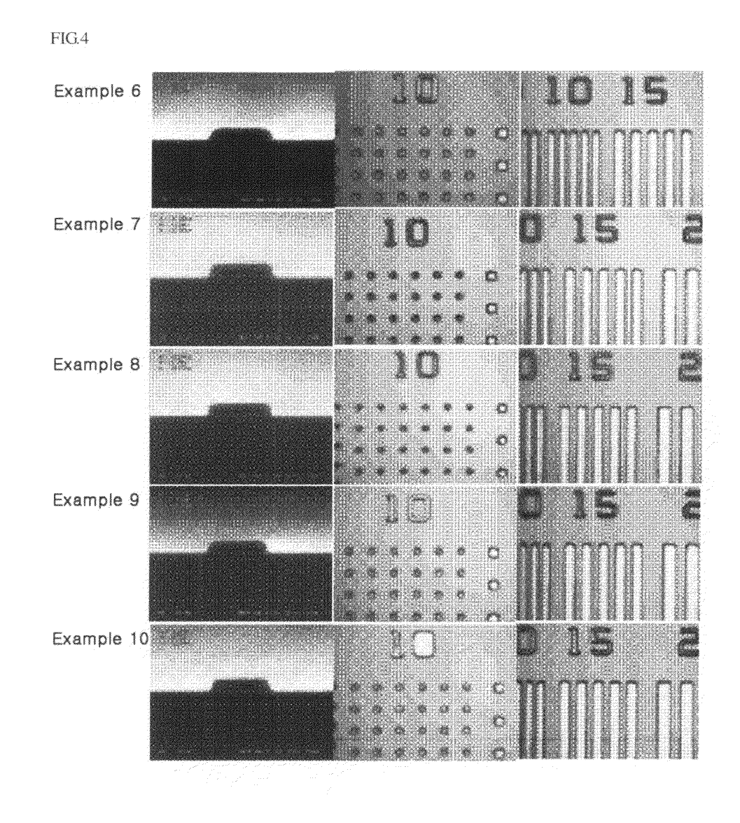

FIG. 4 is a photographic view of the barrier ribs produced according to Examples 6-10 taken by SEM after the exposure, development and hard baking.

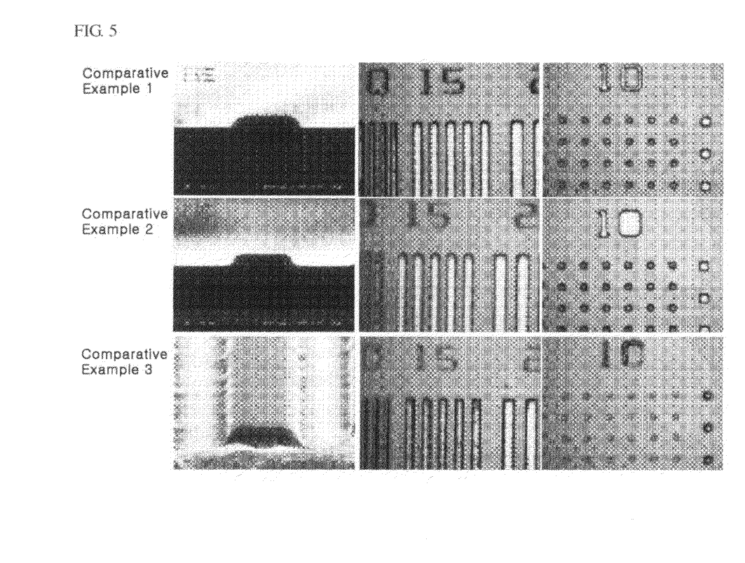

FIG. 5 is a photographic view of the barrier ribs produced according to Comparative Examples 1-3 taken by SEM after the exposure, development and hard baking.

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations and shapes will be determined in part by the particular intended application and use environment.

In the figures, reference numerals refer to the same or equivalent parts of the present invention throughout the figures of the drawing.

Hereinafter, reference will now be made in detail to various embodiments of the present invention, examples of which are illustrated in the accompanying drawings and described below. While the invention will be described in conjunction with example embodiments, it will be understood that the present description is not intended to limit the invention to those example embodiments.

As used herein, the term “alkyl” includes straight-chain, branched and cyclic alkyl groups. Likewise, the terms “alkenyl” and “alkynyl” includes straight-chain, branched and cyclic alkenyl and alkynyl, respectively. The term “(meth)acrylic” includes both acrylic and methacrylic. Likewise, the terms “(meth)acrylate” and “(meth)acryloyl” include both acrylate and methacrylate, and acryloyl and methacryloyl, respectively.

In one aspect, the present invention provides a photosensitive resin composition including 100 parts by weight of a photosensitive resin composition and 50-1,000 parts by weight of a solvent, wherein the photosensitive resin composition includes:

(A) 100 parts by weight of a first polymer including as polymerized units (a1) 10-70 wt % of a radical reactive monomer having a C₄-C₃₀ alkyl, C₄-C₃₀ alkenyl, C₄-C₃₀ aryl, C₄-C₃₀ aralkyl or C₄-C₃₀ alkylaryl group, (a2) 3-40 wt % of monomer selected from (meth)acrylic acid, vinyl alcohol and vinyl thiol, (a3) 5-40 wt % of (meth)acrylate end-capped with (meth)acryl group or 3-acryloyloxy-2-hydroxypropyl group, and (a4) 5-30 wt % of a radical reactive monomer having a fluoro-substituted C₄-C₃₀ alkyl, fluoro-substituted C₄-C₃₀ alkenyl, fluoro-substituted C₄-C₃₀ aryl, fluoro-substituted C₄-C₃₀ fluoro-substituted C₄-C₃₀ aralkyl or fluoro-substituted C₄-C₃₀ alkylaryl group;

(B) 50-120 parts by weight of a multi-functional (meth)acrylate monomer; and

(C) 1-20 parts by weight of a photoinitiator.

The above photosensitive resin is super-hydrophobic and is suitable for forming barrier ribs for LCD pixels.

The present invention further provides a method of forming barrier ribs for LCD pixels including coating the above-described photosensitive resin composition onto an LCD substrate, followed by patterning and developing the photosensitive resin composition.

A particular example of the above described first polymer (A) includes a polymer represented by the following Formula 1:

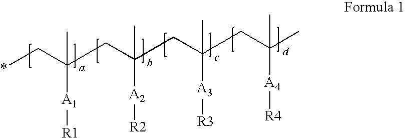

wherein each A₁, A₂, A₃ and A₄ is independently selected from —O—, —COO—, —COO—, —S—, —CONH—, —NHCO—, and a covalent bond; each R1 is independently selected from C₄-C₃₀ alkyl, C₄-C₃₀ alkenyl, C₄-C₃₀ alkenynyl, C₄-C₃₀ aralkyl, C₄-C₃₀ alkylaryl, and C₄-C₃₀ aryl; each R2 is independently selected from fluoro-substituted C₄-C₃₀ alkyl, fluoro-substituted C₄-C₃₀ alkenyl, fluoro-substituted C₄-C₃₀ alkynyl, fluoro-substituted C₄-C₃₀ aralkyl, fluoro-substituted C₄-C₃₀ alkylaryl, and fluoro-substituted C₄-C₃₀ aryl; each R3 is independently selected from —COOH, —OH and —SH; each R4 is a moiety that undergoes a reaction under heat or light, and each of a, b, c and d is a mole fraction excluding 0, wherein a+b+c+d is 1. R4 particularly includes at least one group selected from epoxy, (meth)acrylate, (meth)acryloyloxyalkyl and 3-acryloyloxy-2-hydroxypropyl.

Each monomer unit forming the first polymer is preferably used in the above-described weight ratio. When the amount of the monomer units forming the first polymer is outside the above range, the polymer generally cannot realize sufficient hydrophobicity or may be re-absorbed onto the resultant pattern after development. Particularly, when ingredient (a3) is used in an amount lower than the above range, the resultant polymer shows an excessively lowered crosslinking density, resulting in a problem related to a severe film thickness loss. On the other hand, when ingredient (a3) is used in an amount higher than the above range, it may cause storage stability or other problems including scum generation. It will be appreciated by those skilled in the art that more than one of each monomer type may be used in the first polymer. Although there is no particular limitation in the molecular weight of the first polymer, the first polymer preferably has a number average molecular weight of 500-100,000, and more preferably of 1,000-50,000.

In another aspect, the present invention provides a photosensitive resin composition by diluting 100 parts by weight of a photosensitive resin composition with 50-1,000 parts by weight of a solvent, wherein the photosensitive resin composition includes:

(A) 100 parts by weight of a blended polymer of (A1) a first polymer with (A2) a second polymer, wherein the first polymer (A1) includes as polymerized units (a11) 10-70 wt % of a radical reactive monomer having a C₄-C₃₀ alkyl, C₄-C₃₀ alkenyl, C₄-C₃₀ aryl, C₄-C₃₀ aralkyl or C₄-C₃₀ alkylaryl group, (a12) 3-40 wt % of a monomer selected from (meth)acrylic acid, vinyl alcohol and vinyl thiol, (a13) 5-40 wt % of a (meth)acrylate end-capped with (meth)acryl group or 3-acryloyloxy-2-hydroxypropyl group, and (a14) 5-30 wt % of a radical reactive monomer having a fluoro-substituted C₄-C₃₀ alkyl, fluoro-substituted C₄-C₃₀ alkenyl, fluoro-substituted C₄-C₃₀ aryl, fluoro-substituted C₄-C₃₀ aralkyl or fluoro-substituted C₄-C₃₀ alkylaryl group; and the second polymer (A2) includes as polymerized units (a21) 10-70 wt % of a radical reactive monomer having a C₄-C₃₀ alkyl, C₄-C₃₀ alkenyl, C₄-C₃₀ aryl, C₄-C₃₀ aralkyl or C₄-C₃₀ alkylaryl group, (a22) 5-30 wt % of (meth)acrylic acid, and (a23) 5-40 wt % of (meth)acrylate end-capped with (meth)acryl group or 3-acryloyloxy-2-hydroxypropyl group;

(B) 50-120 parts by weight of a multi-functional (meth)acrylate monomer; and

(C) 1-20 parts by weight of a photoinitiator.

The above photosensitive resin is super-hydrophobic and is suitable for forming barrier ribs for LCD pixels.

Preferably, the first polymer and the second polymer are used in a weight ratio of 1:0.01-1:12 (first polymer:second polymer) so as to realize desired super-hydrophobicity and basic physical properties required for barrier ribs.

A particular example of ingredient (A2) includes a polymer represented by the following Formula 2:

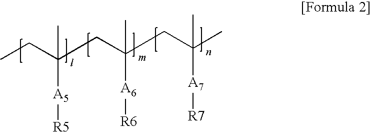

wherein each A₅, A₆ and A₇ are independently selected from —O—, —COO—, —COO—, —S—, —CONH—, —NHCO—, and a covalent bond; each R5 is independently selected from C₄-C₃₀ alkyl, C₄-C₃₀ alkenyl, C₄-C₃₀ alkynyl, C₄-C₃₀ aralkyl, C₄-C₃₀ alkylaryl, and aryl; each R6 is independently selected from —COOH, —OH and —SH; each R7 is a moiety that undergoes a reaction under heat or light; and each of l, m and n is a mole fraction excluding 0, wherein 1+m+n is 1. R7 particularly includes at least one group selected from epoxy, (meth)acrylate, (meth)acryloyloxyalkyl group and 3-acryloyloxy-2-hydroxypropyl.

Each unit forming the first polymer (A1) is preferably used in the above weight ratio. When the amount of each monomer unit forming the first polymer (A1) is used in an amount outside the above range, the material cannot realize sufficient hydrophobicity or may be readsorbed onto the resultant pattern after development. Particularly, when ingredient (a3) is used in an amount lower than the above range, the resultant polymer shows an excessively lowered crosslinking density, resulting in a problem related to a severe film thickness loss. On the other hand, when ingredient (a3) is used in an amount higher than the above range, it may cause storage stability or other problems including scum generation.

According to the present invention, it is preferable for the blended polymer to have a high alkali dissolution rate (ADR). However, the two polymers may have an adequate difference in dissolution rates. Alternatively, the blended polymer may have a high acid value (AV). It is important that the blended polymer has an AV of 20-1,000, and more preferably of 30-500. Although there is no particular limitation in the molecular weights of the first polymer and the second polymer, each polymer preferably has a number average molecular weight of 500-100,000, and more preferably of 1,000-50,000.

In still another aspect, the present photosensitive resin composition optionally comprises an adhesion promoter. Typically, the adhesion promoter is present in an amount of 0.01-5 parts by weight based on 100 parts by weight of the first polymer, even if a blended polymer is used There is no particular limitation in the adhesion promoter, as long as the adhesion promoter is an alkoxysilane-based material. Particular examples of such materials include, without limitation, alkoxysilane compounds such as 3-vinyltrimethoxysilane, 3-vinyltriethoxysilane, and trimethoxysilylbutyl methacrylate. An epoxy or glycidyloxy structure represented by the following Formula 3 is preferred:

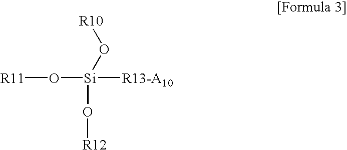

wherein A₁₀ is an epoxy group, (meth)acryl group, amino group, carboxyl group or hydroxyl group; each of R10-R12 is independently selected from methyl, ethyl, propyl and butyl; and R13 is a saturated or unsaturated hydrocarbyl group. The compounds of Formula 3 are preferred because the use of such a glycidyloxy group-containing alkoxysilane realizes improved adhesion of the composition and barrier ribs obtained therefrom to a glass substrate.

In yet another aspect, the present i photosensitive resin composition optionally comprises a UV quencher. The presence of such a UV quencher provides a slow curing rate upon photocuring, thereby improving the uniformity of a cured pattern on a glass substrate.

There is no particular limitation in the UV quencher, as long as the UV quencher is one used in photopolymerization, and particular examples thereof include a quinone compound such as hydroquinone, methylhydroquinone, anthraquinone, para-benzoquinone or t-butylhydroquinone, or TEMPO (tetramethylpiperidine-oxyl) compounds such as tetramethylpiperidine-1-oxyl, 4-hydroxy-tetramethylpiperidine-1-oxyl, 4-amino-tetramethylpiperidine-1-oxyl or 4-oxo-tetramethylpiperidine-1-oxyl. The quenching agent is used in an amount of 0.1-20 parts by weight based on 100 parts by weight of the first polymer (when only the first polymer is used) or the blended polymer (when both the first polymer and the second polymer are used) to prevent excessive lowering of the reaction rate and to improve the surface uniformity by inhibiting severe photocuring.

As the photoinitiator (C), photoinitiators for ghi-line exposure may be used with no particular limitation. Particular examples of the photoinitiator that may be used in the present invention include alpha-hydroketones, alpha-hydroacetophenones, alpha-aminoketones, alpha-aminoacetophenones, benzyl dimethyl ketals, phosphine oxides, trichlorotriazines, and oxime esters. Oxime esters are preferred in view of the sensitivity (photoreactivity), reaction rate and solubility in the solvent used in the composition according to the present invention.

The present photosensitive resin composition includes a solvent. There is no particular limitation in the solvent used, as long as the solvent can dissolve the ingredients forming the composition. However, ester solvents are preferred in view of the solubility. Particular examples of the solvent that may be used in the present invention include methylmethoxypropionate (MMP), ethyl lactate (EL), methyl ethyl ketone (MEK), cyclohexanone (CHON), ethyl CELLOSOLVE solvent (EC), butyl CELLOSOLVE solvent (BC), propyl cellosolve (PrC), propylene glycol methyl ether acetate (PGMEA), propylene glycol monomethyl ether (PGME), dipropylene glycol dimethyl ether (DPGDME), or the like.

The multi-functional (meth)acrylate monomer (B) that may be used in the present compositions includes a monomer having at least two (meth)acrylate groups. The multi-functional (meth)acrylate monomer may be selected considering the desired strength or physical properties of barrier ribs to be produced from the composition according to the present invention. Particular examples of the multi-functional (meth)acrylate monomer include dipentaerythritol hexaacrylate (DPHA), pentaerythritol tetraacrylate (PETA), trimethylolpropane triacrylate (TMPTA), ethoxylated trimethylolpropane triacrylate (TMPEOTA), hexanediol diacrylate (HDDA), ethoxylated hexanediol diacrylate (HDEODA), 2-hydroxypropyl diacrylate (2-HPA), isobornyl diacrylate, polyethylene glycol diacrylate (PEGDA), and polymeric multi-functional (meth)acrylates such as polyurethane diacrylate, polyurethane triacrylate, polyurethane tetraacrylate, polyether diacrylate or polyester diacrylate having a molecular weight of 200-10,000. Such monomers may be used alone or in combination.

In addition, the photosensitive resin composition according to the present invention optionally further comprises conventional additives including a defoaming agent, viscosity modifier, flame retardant, etc., as necessary. The amount of such additives is determined in such a manner that the presence of the additives does not adversely affect the super-hydrophobicity or developability of the composition according to the present invention.

Hereinafter, a process for forming barrier ribs for LCD pixels according to the present invention will be explained.

The process for forming barrier ribs in an LCD by using the photosensitive resin composition according to the present invention is based on UV curing and thermal curing of the photosensitive resin selected for each aspect of the present invention in order to realize super-hydrophobicity.

While not wishing to be bound by theory, it is believed that the polymer chain forming the photosensitive resin according to the present invention undergoes surface reconstruction to minimize its surface energy depending on the circumstance conditions. In other words, a part of the polymer with relatively higher hydrophobicity, such as a side chain containing a hydrophobic group, tends to move toward a surface when the surface is in contact with the air, while a part of the polymer with relatively higher hydrophilicity tends to hide into the binder. The basic concept of the present invention is in fixing and maximizing such a fundamental surface reconstruction phenomenon.

According to the present invention, a suitable side chain containing a hydrophobic group is exemplified by a long-chain alkyl group or fluoro-substituted long chain alkyl group wherein the side chain has at least four carbon atoms so that the chain can move easily (step 1, FIG. 1), thereby maximizing surface reconstruction of the hydrophobic part. Then, the hydrophobic side chain preliminarily protruding out from the backbone by such a sufficient length is subjected to UV curing and is fixed on the surface in order to prevent reversion of the side chain during the subsequent development step essentially required for patterning.

Herein, the curing degree is in proportion to the number of reactive sites. Therefore, the multi-functional monomer is used for such fixing to accomplish the curing to the maximum density (step 2, FIG. 1). Finally, the polymer is further subjected to curing during a hard bake step after the development step, depending on the kinds of functional groups substituted on the polymer chain, so as to recover a partial surface structure that might have been reversed in the preceding steps, and to reinforce the curing (step 3, FIG. 2).

As can be seen from the foregoing, the present invention provides a transparent negative-tone photosensitive material for ink jet printing, which has super-hydrophobicity characterized by a contact angle value of >90° to distilled water and a contact angle value of >35° to ethylCELLOSOLVE solvent, is sufficiently dissolved in a developing agent before and after exposure, and can realize a micropattern with a size up to 15 μm, preferably up to 10 μm. The barrier ribs for LCD pixels obtained by using the super-hydrophobic photosensitive resin composition according to the present invention realize sufficient adhesion and high wetting ability of inks when an ink jet printing step is performed by using RGB (red, green and blue) inks (i.e., when the RGB inks are sprayed or dropped into developed cells by way of ink jet printing) after the formation of the barrier ribs for LCD pixels. Additionally, the barrier ribs (i.e. pattern for forming the pixels) formed from the composition ensure such an extreme degree of hydrophobicity that the inks maintain their droplets in one cell without overflowing toward another cell in spite of an excessive dropping amount. As a result, the present invention can simplify the overall process for fabricating an LCD while minimizing defects during the fabrication.

### EXAMPLE 1

The following ingredients were mixed: 73.20 g (solid content 15.8 wt %) of a first polymer (weight average molecular weight 15,000) containing octyl methacrylate, methacrylic acid, perfluorohexyl methacrylate and 3-acryloyloxy-2-hydroxypropyl methacrylate units in a molar ratio of 1:0.5:0.5:0.5;

3.14 g (solid content 36.9 wt %) of a second polymer (weight average molecular weight 22,000) containing octyl methacrylate, methacrylic acid and 3-acryloyloxy-2-hydroxypropyl methacrylate units in a molar ratio of 1:0.5:0.5;

10.98 g of dipentaerythritol hexaacrylate;

1.73 g of polyurethane diacrylate having a number average molecular weight of 3000 (Kayarad UXE3024 available from Nippon Kayaku Co.);

4.0 g of an oxime ester initiator (Irgacure 369 available from Ciba Geigy Corp.);

0.5 g of 3-glycidoxypropyl trimethoxysilane;

0.5 g of a coating improver (EFKA 2035 available from Ciba Geigy Corp.); and

48 g of propylene glycol methyl ether acetate.

The resultant mixture was violently agitated for three hours to provide a super-hydrophobic photosensitive resin solution, which, in turn, was coated onto a glass substrate with a size of 10 mm×10 mm by using an SUSS Microtec GAMMA instrument. The photosensitive resin solution is coated onto the glass substrate in an amount of 4 cc per unit area of the glass substrate. Next, a resist layer was spin coated to a coating thickness of 38000±500 Å, and a soft bake step was carried out at 105° C. for 90 seconds, followed by cooling, to provide a glass substrate.

The glass substrate was coated with a photoresist layer by using a pattern mask and was introduced into an SUSS Microtec MA-6 ghi-line exposure system to perform an exposure step under a dose of 22.0 mW (365 nm, 1-line wavelength) with a proximity gap of 50 μm. Next, the glass substrate was subjected to swing under 50 rpm while it was dipped in 0.4 wt % TMAH (teteramethylammonium hydroxide) developer at 25±0.5° C. for 150 seconds, was rinsed with distilled water, and dewatered by using an air gun. Then, the glass substrate was further subjected to thermal curing in a convection oven at 220° C. for 60 minutes. The profile of the resultant pattern was monitored and each contact angle value to ethyl cellosolve and water (H₂O) was determined. The results are shown in FIG. 3 and Table 1.

### EXAMPLE 2

Example 1 was repeated except that the weight ratio of the first polymer:the second polymer (weight average molecular weight 15,000) was 1:1 on the solid content basis. The results are shown in FIG. 3 and Table 1.

### EXAMPLE 3

Example 1 was repeated except that the weight ratio of the first polymer:the second polymer (weight average molecular weight 10,000) was 1:2 on the solid content basis, and FZ1225 (Dow Corning Toray Co.) was used as a coating improver. The results are shown in FIG. 3 and Table 1.

### EXAMPLE 4

Example 1 was repeated except that the weight ratio of the first polymer (weight average molecular weight 25,000):the second polymer (weight average molecular weight 10,000) was 1:9 on the weight basis, and 1.0 g of 4-hydroxy-TEMPO (Tokyo Kasei Kogyo) was further added as a UV quencher. The results are shown in FIG. 3 and Table 1.

### EXAMPLE 5

Example 3 was repeated except that polyurethane diacrylate was not used, dipentaerythritol hexaacrylate was used in the same amount as the solid content of the first polymer and the second polymer, and the oxime ester initiator was changed and reduced from 4.0 g of Irgacure 369 to 1.0 g of Irgacure OXE-02 (Ciba Geigy Corp.). The results are shown in FIG. 3 and Table 1.

### EXAMPLE 6

Example 1 was repeated except that the oxime ester initiator was changed and reduced from 4.0 g of Irgacure 369 to 2.0 g of Irgacure OXE-01 (Ciba Geigy Corp.).

### EXAMPLE 7

Example 5 was repeated except that dipentaerythritol hexaacrylate was used in an amount corresponding to 80% of the original amount, 2 parts by weight of polyurethane diacrylate was used based on 100 parts by weight of dipentaerythritol hexaacrylate, and 0.3 g of 4-hydroxy-TEMPO (Tokyo Kasei Kogyo) was further added as a UV quencher. The results are shown in FIG. 4 and Table 1.

### EXAMPLE 8

Example 2 was repeated except that dipentaerythritol hexaacrylate and polyurethane diacrylate were used in a weight ratio of 1:1 but in the same combined weight. The results are shown in FIG. 4 and Table 1.

### EXAMPLE 9

Example 5 was repeated except that dipentaerythritol hexaacrylate was used in an amount corresponding to 50% of the original amount and the balance amount of pentaerythritol tetraacrylate (NK ESTER CBX-1N, Shinnakamura Co.) was used. The results are shown in FIG. 4 and Table 1.

### EXAMPLE 10

Example 8 was repeated except that methoxymethyl propionate was used instead of propylene glycol methyl ether acetate as the solvent. The results are shown in FIG. 4 and Table 1.

TABLE 1
Contact Angle Values of Examples and Blanks

| | Patterning ability | | Contact angle value | | | |
|---|---|---|---|---|---|---|
| | L/S (15 μm) | C/H (10 μm) | Pattern | | Blank | |
| Examples | Spec: 16-18 | Open | EC | DIW | EC | DIW |
| 1 | 17.30 | O.K. | 64.2 | 121.6 | <5 | 59.8 |
| 2 | 16.98 | O.K. | 52.8 | 101.1 | <5 | 60.3 |
| 3 | 17.11 | O.K. | 53.5 | 102.0 | <5 | 64.7 |
| 4 | 16.33 | O.K. | 49.0 | 100.5 | <5 | 66.1 |
| 5 | 17.76 | O.K. | 46.2 | 100.6 | <5 | 57.0 |
| 6 | 16.85 | O.K. | 64.5 | 122.1 | <5 | 60.8 |
| 7 | 17.51 | O.K. | 55.3 | 103.8 | <5 | 57.2 |
| 8 | 17.58 | O.K. | 49.5 | 105.4 | <5 | 65.5 |
| 9 | 16.77 | O.K. | 51.0 | 105.3 | <5 | 66.1 |
| 10 | 16.79 | O.K. | 48.7 | 104.2 | <5 | 64.0 |

The quality of the photoresist pattern according to each Example was evaluated by performing a lithographic test and measuring the contact angle value. In the lithographic test, a smaller pattern size of a mask used for exposure provides higher resolution. Also, the lithographic test determines whether such a small pattern size is accurately transferred onto a glass substrate without any change or not. As can be seen from the results in Table 1, in the case of 15 μm line-and-space (L/S) mask patterns, the patterns are formed normally in a range of 16-18 μm, which is generally acceptable in the current LCD fabrication processes. Also, relatively small size patterns, i.e., 10.0 μm contact hole (C/H) patterns are opened in all cases, but not completely. When the holes are not opened in the patterns, metal interconnections for transferring electric signals cannot be made from the TFT. Therefore, such patterns cannot be used as a patterning material in a practical semiconductor or LCD fabrication process. The above two lithographic test results determine whether a high-sensitivity developable negative photoresist is formed or not. In addition, measurement of contact angle values determines whether the photoresist ensures sufficient hydrophobicity and hydrophilicity or not. In the above test, each of the photosensitive resin compositions according to Examples 1-10 showed a contact angle value of at least 45° on the pattern forming the outer walls of pixels, as measured in ethyl CELLOSOLVE solvent (at least 90° as measured in distilled water). This means that each photosensitive resin composition has super-hydrophobicity. On the contrary, in the inner part of the developed pixels, each photosensitive resin composition showed high hydrophilicity characterized by a contact angle value of about 59°-66°, as measured in distilled water (DIW) (<10° as measured in ethyl CELLOSOLVE solvent). It can be seen from the above results that the photosensitive resin composition according to the present invention realizes excellent wettability of RGB inks in the inner part of LCD pixels due to such high hydrophilicity, when an ink jet printing step is carried out by spraying or dropping the RGB inks into the LCD pixels, while the super-hydrophobic barrier ribs formed from the composition completely separate the pixels to prevent the inks from overflowing even though the ink loading amount increases.

### COMPARATIVE EXAMPLE 1

Example 1 was repeated except that the first polymer was not used and the same amount of the second polymer substituted for the first polymer to provide a resin solution. The results are shown in FIG. 5 and Table 2.

### COMPARATIVE EXAMPLE 2

Example 1 was repeated except that the weight ratio of the first polymer (weight average molecular weight 25,000):the second polymer (weight average molecular weight 10,000) was 1:15, and 1.0 g of TEMPO (Tokyo Kasei Kogyo) was further added as a UV quencher. The results are shown in FIG. 5 and Table 2.

### COMPARATIVE EXAMPLE 3

Comparative Example 2 was repeated except that the first polymer having fluorine-containing groups was not used and another first polymer (weight average molecular weight 15,000) having the same proportion of C₁₈ linear alkyl groups instead of the fluorine-containing groups was used. The results are shown in FIG. 5 and Table 2.

TABLE 2
Contact Angle Values of Examples and Blanks

| | Patterning ability | | Contact angle value | | | |
|---|---|---|---|---|---|---|
| Comparative | L/S (15 μm) | C/H (10 μm) | Pattern | | Blank | |
| Examples | Spec: 16-18 | Open | EC | DIW | EC | DIW |
| 1 | 18.09 | O.K. | 8.6 | 76.7 | <5 | 63.3 |
| 2 | 17.75 | O.K. | 20.8 | 87.9 | <5 | 56.7 |
| 3 | — | N.G. | 15.3 | 81.7 | <5 | 83.8 |

As can be seen from the results of Table 2, in the case of 15 μm line-and-space (L/S) mask patterns, Comparative Examples 1 and 2 are within the acceptable range or show a slightly larger value. Additionally, 10.0 μm contact hole (C/H) patterns are opened in both Comparative Examples. This suggests that Comparative Examples 1 and 2 are not significantly different from the inventive Examples in terms of the lithographic test in spite of the use of a decreased amount of the first polymer or even the absence of the first polymer. However, Comparative Examples 1 and 2 cannot ensure the most important characteristic, i.e., super-hydrophobicitiy, and thus cannot be applied to an ink jet printing step even if they provide high-resolution photoresist. Additionally, in the case of Comparative Example 3 using a composition merely having a long linear alkyl chain, any significant difference in developability cannot be seen before and after development when the composition according to Comparative Example 3 is used as a photoresist layer. Thus, it is not possible to form a desired pattern and to realize desired super-hydrophobicity. Instead, the blank regions requiring hydrophilicity still show high hydrophobicity. This suggests that although a photosensitive resin composition having a modified composition is used to form a pattern as photoresist, it cannot be applied to an ink jet printing step, in principle. As can be seen from the all above results, photoresist that merely ensures good resolution cannot realize desired super-hydrophobicity, and the photosensitive resin composition free from the first polymer as defined herein cannot be applied to an ink jet printing step.

As can be seen from the foregoing, the present invention provides a super-hydrophobic photosensitive resin composition for forming barrier ribs in an LCD, which has both super-hydrophobicity and hydrophilicity. Therefore, the present invention can realize a simple LCD fabrication process, and can minimize consumption of color inks by preventing intermix of RGB inks even when RGB inks are sprayed (or dropped) simultaneously under an increased ink loading amount by virtue of the super-hydrophobicity of the barrier ribs formed from the composition. Additionally, the present invention can simplify the overall process for fabricating an LCD by avoiding a need for a photomask in a coloring step. Further, the super-hydrophobic photosensitive resin composition can be applied to a part requiring protection from water.

The invention has been described in detail with reference to preferred embodiments thereof. However, it will be appreciated by those skilled in the art that changes may be made in these embodiments without departing from the principles and spirit of the invention, the scope of which is defined in the accompanying claims and their equivalents.

What is claimed is:

1. A photosensitive resin composition, comprising 100 parts by weight of a photosensitive resin composition and 50-1,000 parts by weight of a solvent, wherein the photosensitive resin composition comprises:
(A) 100 parts by weight of a first polymer comprising as polymerized units (a1) 10-70 wt % of a radical reactive monomer having a C₄-C₃₀ alkyl, C₄-C₃₀ alkenyl, C₄-C₃₀ aryl, C₄-C₃₀ aralkyl or C₄-C₃₀ alkylaryl group, (a2) 3-40 wt % of at least one monomer selected from (meth)acrylic acid, vinyl alcohol and vinyl thiol, (a3) 5-40 wt % of (meth)acrylate end-capped with (meth)acryl group or 3-acryloyloxy-2-hydroxypropyl group, and (a4) 5-30 wt % of a radical reactive monomer having a fluoro-substituted C₄-C₃₀ alkyl, fluoro-substituted C₄-C₃₀ alkenyl, fluoro-substituted C₄-C₃₀ aryl, fluoro-substituted C₄-C₃₀ aralkyl or fluoro-substituted C₄-C₃₀ alkylaryl group;
(B) 50-120 parts by weight of a multi-functional (meth)acrylate monomer; and
(C) 1-20 parts by weight of a photo initiator.

2. A photosensitive resin composition, comprising 100 parts by weight of a photosensitive resin composition optionally with 50-1,000 parts by weight of a solvent, wherein the photosensitive resin composition comprises:
(A) 100 parts by weight of a blended polymer of (A1) a first polymer with (A2) a second polymer, wherein the weight ratio of the first polymer:the second polymer is 1:0.01-12, the first polymer (A1) comprising as polymerized units (a11) 10-70 wt % of a radical reactive monomer having a C₄-C₃₀ alkyl, C₄-C₃₀ alkenyl, C₄-C₃₀ aryl, C₄-C₃₀ aralkyl or C₄-C₃₀ alkylaryl group, (a12) 3-40 wt % of a monomer selected from (meth)acrylic acid, vinyl alcohol and vinyl thiol, (a13) 5-40 wt % of a (meth)acrylate end-capped with (meth)acryl group or 3-acryloyloxy-2-hydroxypropyl group, and (a14) 5-30 wt % of a radical reactive monomer having a fluoro-substituted C₄-C₃₀ alkyl, fluoro-substituted C₄-C₃₀ alkenyl, fluoro-substituted C₄-C₃₀ aryl, fluoro-substituted C₄-C₃₀ aralkyl or fluoro-substituted C₄-C₃₀ alkylaryl group, and the second polymer (A2) comprises as polymerized units (a21) 10-70 wt % of a radical reactive monomer having a C₄-C₃₀ C₄-C₃₀ alkyl, C₄-C₃₀ alkenyl, C₄-C₃₀ aryl, C₄-C₃₀ aralkyl or C₄-C₃₀ alkylaryl group, (a22) 5-30 wt % of (meth)acrylic acid, and (a23) 5-40 wt % of (meth)acrylate end-capped with (meth)acryl group or 3-acryloyloxy-2-hydroxypropyl group;
(B) 50-120 parts by weight of a multi-functional (meth)acrylate monomer; and
(C) 1-20 parts by weight of a photoinitiator.

3. The photosensitive resin composition of claim 2, wherein the photosensitive resin composition when formed into a film has a contact angle value of >90° to distilled water and a contact angle value of >35° to ethyl CELLOSOLVE solvent.

4. The photosensitive resin composition of claim 3, wherein the first polymer and the second polymer are represented by the following Formula 1 and Formula 2, respectively: 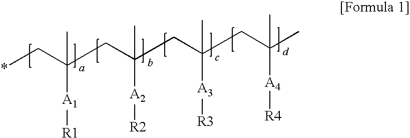
wherein A₁, A₂, A₃ and A₄ each represent —O—, —COO—, —COO—, —S—, —CONH—, —NHCO—, or a covalent bond;
each R1 is selected from C₄-C₃₀ alkyl, C₄-C₃₀ alkenyl, C₄-C₃₀ aralkyl, C₄-C₃₀ alkylaryl, and C₄-C₃₀ aryl;
each R2 is selected from fluoro-substituted alkyl, fluoro-substituted aralkyl, fluoro-substituted alkylaryl, and fluoro-substituted aryl;
each R3 is selected from —COOH, —OH and —SH;
R4 is a moiety that undergoes a reaction under heat or light; and
each of a, b, c and d is a mole fraction excluding 0, wherein a+b+c+d is 1; and 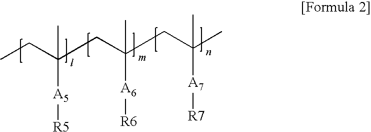
wherein A₅, A₆ and A₇ are each selected from —O—, —COO—, —COO—, —S—, —CONH—, —NHCO—, and a covalent bond;
each R5 is selected from C₄-C₃₀ alkyl, C₄-C₃₀ aralkyl, C₄-C₃₀ alkylaryl, and C₄-C₃₀ aryl;
each R6 is selected from —COOH, —OH and —SH;
each R7 is a moiety that undergoes a reaction under heat or light; and
each of l, m and n is a mole fraction excluding 0, wherein 1+m+n is 1.

5. The photosensitive resin composition of claim 4, which further comprises 0.01-5 parts by weight of an adhesion promoter based on 100 parts by weight of ingredient (A).

6. The photosensitive resin composition of claim 5, which further comprises 0.1-20 parts by weight of a quenching agent based on 100 parts by weight of ingredient (A).
